(19) United States
(12) Patent Application Publication
(10) Pub. No.: US 2017/0147112 A1
(43) Pub. Date: May 25, 2017

(54) EMBEDDED TOUCH SCREEN AND ORGANIC LIGHT EMITTING DIODE DISPLAY DEVICE

(71) Applicants: Boe Technology Group Co., Ltd., Beijing (CN); Beijing Boe Optoelectronics Technology Co., Ltd., Beijing (CN)

(72) Inventors: Lei Wang, Beijing (CN); Xiaochuan Chen, Beijing (CN); Shengji Yang, Beijing (CN); Xiaoliang Ding, Beijing (CN); Yue Li, Beijing (CN); Weijie Zhao, Beijing (CN); Xiaobo Xie, Beijing (CN)

(21) Appl. No.: 15/108,404

(22) PCT Filed: Dec. 31, 2015
(86) PCT No.: PCT/CN2015/100124

§ 371 Date: Jun. 27, 2016

(30) Foreign Application Priority Data
Jul. 6, 2015 (CN) 201510389330.9

(51) Int. Cl. G06F 3/041; H01L 27/32; H01L 51/52; G06F 3/044

(52) U.S. Cl. CPC G06F 3/0412; G06F 3/044; H01L 27/323; H01L 27/3276; H01L 51/5225; G06F 2203/04111

(57) ABSTRACT

The present disclosure provides an embedded touch screen comprising: an array substrate having a plurality of subpixels, each subpixel comprising an organic light-emitting diode; a plurality of gate lines and data lines arranged on the array substrate which intersect each other and are insulated from each other, the gate lines and the data lines intersecting each other to define the plurality of subpixels; a plurality of self-capacitance electrodes which are arranged in the same layer and independent from each other; and a plurality of touch connecting lines for connecting respective self-capacitance electrodes to a touch detection chip, wherein the self-capacitance electrodes may be arranged in the same layer as anodes of the organic light-emitting diodes. The present disclosure further provides a display device comprising the above embedded touch screen.

### RELATED APPLICATIONS

The present application is the U.S. national phase entry of PCT/CN2015/100124, with an international filing date of Dec. 31, 2015, which claims the benefit of Chinese Patent Application No. 201510389330.9, filed on Jul. 6, 2015, the entire disclosures of which are incorporated herein by reference.

### FIELD

The present disclosure generally relates to the display field, and more specifically to an embedded touch screen and an organic light-emitting diode display device.

### BACKGROUND

Organic light-emitting diode (OLED) display technology, as an extremely promising display technology, has advantages including significantly increased viewing angle, reduced power consumption, improved contrast, decreased screen thickness, fast response time, high luminous efficiency, and the like as compared to the liquid crystal display (LCD) technology, since it employs the mode of self-emitting pixels instead of the common backlight mode.

Touch screen function has become one of the primary forms of modern input modes, which has gradually replaced the traditional mechanical key-press input mode in portable electronic products such as mobile phone, tablet computer, electronic book, and so on, and a full-touch key-free input mode would finally be implemented. It is an advanced technical tend currently to integrate the touch function into a display device.

Touch screens may be divided into a plug-in touch screen, a surface-covered touch screen and an embedded touch screen in terms of the constituent structure, wherein the plug-in touch screen is a liquid crystal display screen having touch function which is formed by producing the touch screen and the liquid crystal display screen separately and then attaching them together. The plug-in touch screen involves disadvantages including high manufacture cost, low light transmittance, relatively thick modules, and the like. In contrast, the embedded touch screen is to embed the touch electrodes of the touch screen within the liquid crystal display screen, which can not only decrease the overall thickness of the modules but also reduce the manufacture cost of the touch screen significantly, hence it is preferred by panel manufacturers.

Currently, the existing embedded touch screen detects the position touched by a finger using the mutual capacitance or self-capacitance principle. Taking a touch screen device sold under the trademark Iphone® 5 of Apple Corporation, USA as an example, it employs an embedded touch screen based on mutual capacitance and makes the capacitor electrodes on the array substrate. Relative to conventional array processes, the array process of the embedded touch screen is additionally added with at least two masks and at least two photolithography process steps, resulting in an increase in the manufacture cost.

By comparison, the self-capacitance principle is to arrange in the touch screen a plurality of self-capacitor electrodes which are arranged in the same layer and are insulated from each other. When the human body does not touch the screen, the capacitances on respective self-capacitance electrodes are of a certain fixed value; when the human body touches the screen, the capacitances on corresponding self-capacitance electrodes are of the fixed value plus the capacitance of the human body. A touch detection chip can determine the touch position by detecting variations in the capacitance values of the respective capacitor electrodes during a touch time period. Since the capacitance of the human body can act on all of the self capacitances, as compared to the case that the capacitance of the human body can only act on the projective capacitances in the mutual capacitances, the amount of variation in touch resulting from touching the screen by the human body would be larger than that in the touch screen made using the mutual-capacitance principle. Therefore, the self capacitance-based touch screen can efficiently increase the signal-to-noise ratio of the touch signal as compared to the mutual capacitance-based touch screen, thereby improving the accuracy of touch sensing.

### SUMMARY

It is one objective of the present disclosure to overcome at least some of the above disadvantages, and to provide an improved embedded touch screen and display device.

In accordance with one aspect of the present disclosure, an embedded touch screen is provided, which may comprise: an array substrate having a plurality of subpixels, each subpixel comprising an organic light-emitting diode; a plurality of gate lines and data lines arranged on the array substrate which intersect each other and are insulated from each other, the gate lines and the data lines intersecting each other to define the plurality of subpixels; a plurality of self-capacitance electrodes which are arranged in the same layer and independent from each other; and a plurality of touch connecting lines for connecting respective self-capacitance electrodes to a touch detection chip, wherein the self-capacitance electrodes may be arranged in the same layer as anodes of organic light-emitting diodes.

The present disclosure achieves the integration of the OLED display with the touch function by integrating the touch technology into an OLED display device. The proposed display device implements the touch functionality based on the self capacitance scheme on the basis of the existing organic light-emitting diode display device, without influencing the pixel characteristics of the display device. The signal-to-noise ratio is significantly increased as compared to the mutual capacitance scheme.

In accordance with an illustrative embodiment of the present disclosure, the anodes of organic light-emitting diodes may be of discrete structure, each anode corresponding to one subpixel, and each self-capacitance electrode may be arranged at a gap between adjacent anodes.

By forming the self-capacitance electrode at an existing gap between anodes, the touch functionality can be implemented on the basis of the existing array substrate manufacturing process, without the need to add additional processes, which can consequently save the production cost and improve the production efficiency.

In accordance with another illustrative embodiment of the present disclosure, the pattern of the self-capacitance electrodes may be designed as a grid pattern which takes the anodes as meshes.

In accordance with a further illustrative embodiment of the present disclosure, the organic light-emitting diode may be a top-emitting structure, wherein the cathode of the organic light-emitting diode has an opening in an area where it overlaps the self-capacitance electrode. By setting the opening, the shielding effect of the cathode on the top of the top-emitting structure on the self-capacitance electrode arranged in the same layer as the anode can be eliminated, thereby enhancing the sensitivity to touch.

In accordance with another illustrative embodiment of the present disclosure, opposite sides of two adjacent self-capacitance electrodes may have zigzag shapes.

In the embedded touch screen provided by embodiments of the present disclosure, since the capacitance of the human body acts on the self capacitances of the self-capacitance electrodes by means of direct coupling, when the human body touches the screen, only the capacitance values of the self-capacitance electrodes below the touch position have a relatively large amount of variation, while there is a very small amount of variation in the capacitance values of other self-capacitance electrodes adjacent to the self-capacitance electrodes below the touch position. In this way, when sliding on the touch screen, the touch coordinates of the area where the self-capacitance electrodes are located cannot be determined. Accordingly, the amount of variation in the capacitance values of the self-capacitance electrodes adjacent to the self-capacitance electrodes below the touch position can be increased by setting the opposite sides of two adjacent self-capacitance electrodes to be zigzag.

In accordance with another illustrative embodiment of the present disclosure, opposite sides of two adjacent self-capacitance electrodes may have consistent and matching step shapes.

In accordance with another illustrative embodiment of the present disclosure, opposite sides of two adjacent self-capacitance electrodes may have consistent and matching convex-concave shapes.

In accordance with another illustrative embodiment of the present disclosure, the self-capacitance electrode may be designed as a square electrode of 5 mm*5 mm.

In accordance with another aspect of the present disclosure, a display device is provided, which comprises the above embedded touch screen.

In accordance with illustrative embodiments of the present disclosure, the display device may be a passive matrix organic light-emitting diode display or an active matrix organic light-emitting diode display.

### BRIEF DESCRIPTION OF DRAWINGS

These and other purposes, features and advantages of the present disclosure would become clearer and more apparent from the following detailed description of illustrative embodiments of the present disclosure with reference to the drawings, wherein the drawings are not drawn to scale. In the drawings,

FIG. 1 is a structural schematic diagram of an organic light-emitting diode (OLED) device;

FIG. 2 is a structural schematic diagram of an embedded touch screen according to illustrative embodiments of the present disclosure;

FIG. 3 is a locally enlarged view of the embedded touch screen as shown in FIG. 2; and

FIGS. 4a and 4b are a structural schematic diagram of adjacent self-capacitance electrodes in the embedded touch screens provided by embodiments of the present disclosure, respectively.

### DETAILED DESCRIPTION

Illustrative embodiments of the present disclosure will be described in detail with reference to the drawings. The drawings are schematic, which are not drawn to scale and are just for illustrating the embodiments of the present disclosure rather than limiting the protection scope of the present disclosure. In the drawings, same reference sign denotes the same or similar components. In order to make the technical solutions of the present disclosure clearer, the process steps and device structures well known in the art are omitted herein.

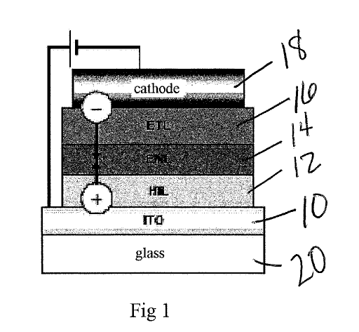

FIG. 1 shows a structural schematic diagram of an OLED device. A indium tin oxide (ITO) film (10) is sputtered on a glass substrate (20) as an anode, and a hole transport layer (HTL) (12) and an electron transport layer (ETL) (16) are formed on the anode, between which a light-emitting layer formed by an organic material is sandwiched. Finally, a cathode layer (18) is deposited on the electron transport layer (16). When the device is applied with an appropriate forward bias voltage, electrons and holes overcome the interface energy barrier and are injected via the cathode and the anode. Electrons are injected into the lowest unoccupied orbital energy level of the electron transport layer via a metal cathode, and holes are injected into the highest occupied orbital energy level of the hole transport layer via a wide bandgap transparent ITO film (10). Driven by an external electric field, the injected electrons and holes transfer to the light-emitting layer in the electron transport layer and the hole transport layer, which are consequently combined with each other within the organic material with luminescent property to form excitons in excited state. The excitons transfer energy to the organic light-emitting molecules and excite transition of the electrons of the organic light-emitting molecules from the ground state to the excited state, and then excite inactivation of the photoelectron radiation so as to generate photons, release energy and return to the stable ground state.

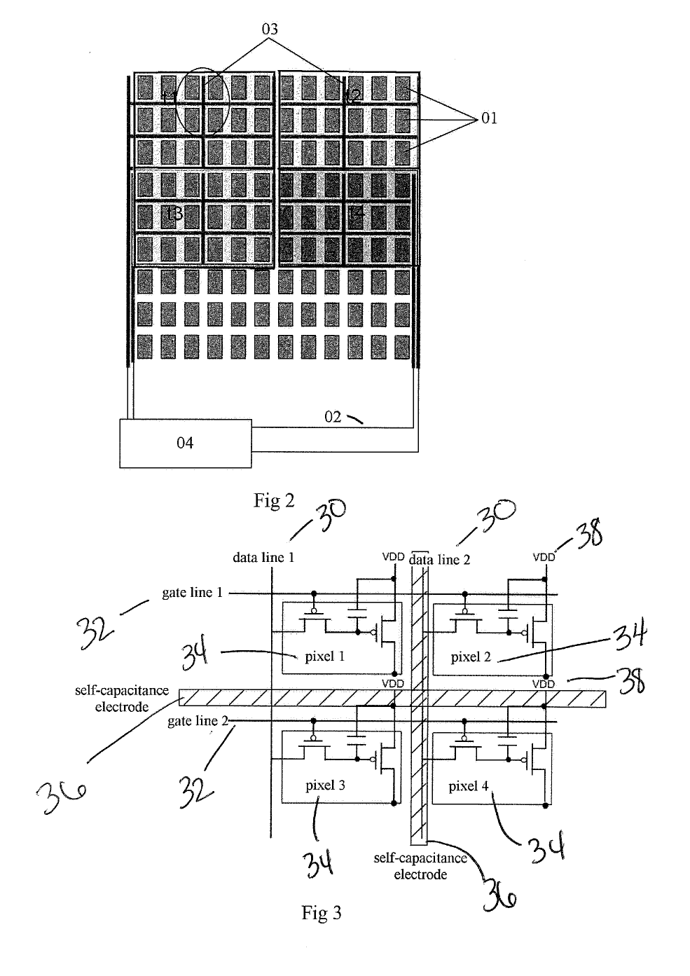

FIG. 2 illustrates a structural schematic diagram of an embedded touch screen according to illustrative embodiments of the present disclosure. The embedded touch screen comprises an array substrate having a plurality of subpixels (01), each subpixel (01) comprising an organic light-emitting diode; a plurality of gate lines and data lines (not shown in FIG. 2) arranged on the array substrate which intersect each other and are insulated from each other, the gate lines and the data lines intersecting each other to define the plurality of subpixels; a plurality of self-capacitance electrodes (03) which are arranged in the same layer and independent from each other; and a plurality of touch connecting lines (02) for connecting respective self-capacitance electrodes to a touch detection chip (04), wherein the self-capacitance electrodes (03) are arranged in the same layer as anodes of the organic light-emitting diodes. The self-capacitance electrodes are connected to the touch detection chip (04) with wires (02), the self-capacitance electrodes (03) are applied with a driving signal Tx via the touch detection chip (04), and the self-capacitance electrodes (03) may receive feedback signals by themselves. Since during the working process, for example, a finger for operation employs the manner of direct coupling, the amount of variation in touch caused by the finger would be relatively large.

FIG. 2 schematically illustrates four self-capacitance electrode patterns t1-t4. Specifically, the anodes of the organic light-emitting diodes are of discrete structure, each anode corresponds to one subpixel (01), and each self-capacitance electrode is arranged at a gap between adjacent anodes to form a grid pattern surrounding the anodes of the organic light-emitting diodes. As shown in FIG. 2, the self-capacitance electrode patterns t1-t4 include row-column network structures formed between 6*3 subpixels (01), and t1-t4 are connected to the touch detection chip 04 respectively via the touch connecting lines (02). The touch functionality can be implemented on the basis of the existing array substrate manufacturing process by forming the self-capacitance electrodes at an existing gap between the anodes of adjacent organic light-emitting diodes, without the need to add additional processes, thus the production cost can be saved and the production efficiency can be improved.

It is to be noted that although FIG. 2 shows the subpixels as rectangles with the same size, those skilled in the art can design the subpixels and corresponding anodes of the organic light-emitting diodes to have different shapes based on practical needs. In addition, the self-capacitance electrodes may be arranged at other positions in the layer where the anodes of the organic light-emitting diodes are located, rather than being limited to the gaps between anodes. Moreover, the pattern of the self-capacitance electrodes is not limited to the grid pattern, either, but any pattern arranged in the same layer as the anodes of the organic light-emitting diodes may be employed, e.g. polygon, annular shape, etc.

When the organic light-emitting diode is a top-emitting structure, the cathode is located at the top, thus it would produce shielding effect on the self-capacitance electrode below it. In order to eliminate the shielding effect, an opening may be arranged in the area where the cathode of the organic light-emitting diode overlaps the self-capacitance electrode.

FIG. 3 illustrates a locally enlarged view of the embedded touch screen in the circle portion as shown in FIG. 2. FIG. 3 shows the portions (shadow portions) between four subpixels 1-4 (34) of the self-capacitance electrode (36) pattern t1 (FIG. 2), wherein the plurality of gate lines (32) and data lines (30) arranged on the array substrate which intersect each other and are insulated from each other define a plurality of subpixels (34).

In the embedded touch screen provided by embodiments of the present disclosure, since the capacitance of the human body acts on the self capacitances of the self-capacitance electrodes by means of direct coupling, when the human body touches the screen, only the capacitance values of the self-capacitance electrodes below the touch position have a relatively large amount of variation, while there is a very small amount of variation in the capacitance values of other self-capacitance electrodes adjacent to the self-capacitance electrodes below the touch position. In this way, when sliding on the touch screen, the touch coordinates of the area where the self-capacitance electrodes are located cannot be determined. Accordingly, the amount of variation in the capacitance values of the self-capacitance electrodes adjacent to the self-capacitance electrodes below the touch position can be increased by setting the opposite sides of two adjacent self-capacitance electrodes to be zigzag.

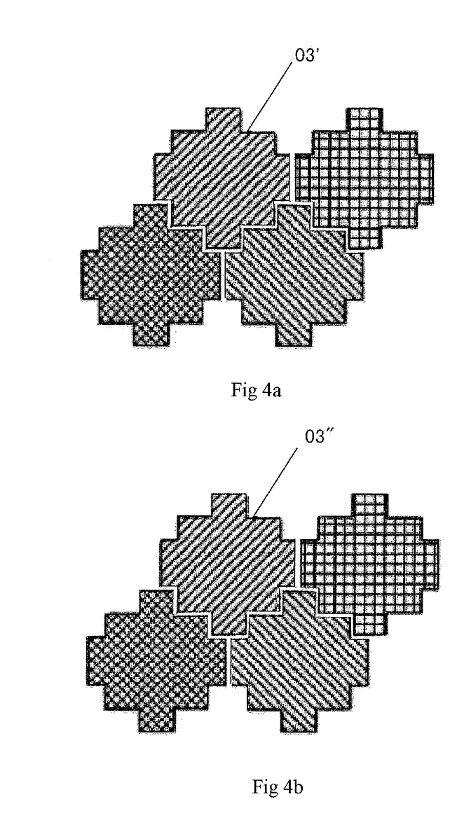

A macro overall shape of the plurality of self-capacitance electrodes may be set in the manner as follows. In FIG. 4a, opposite sides of two adjacent self-capacitance electrodes are set as a step shape, and adjacent step shapes are consistent and match each other. FIG. 4a shows 2*2 self-capacitance electrodes (03′). Alternatively, in FIG. 4b, opposite sides of two adjacent self-capacitance electrodes are both set as a convex-concave shape, and adjacent convex-concave shapes are consistent and match each other. FIG. 4b shows 2*2 self-capacitance electrodes (03″). It is to be noted that although the self-capacitance electrodes are illustrated in FIGS. 4a and 4b as squares whose sides have a zigzag shape, they are just exemplary. The self-capacitance electrodes may have other macro overall shapes, wherein opposite sides of adjacent self-capacitance electrodes (03) have a zigzag shape. In FIGS. 4a and 4b, adjacent self-capacitance electrodes do not contact each other.

Generally, the density of the touch detection is usually at millimeter scale. Therefore, the density of the self-capacitance electrodes and the area occupied by them can be selected based on a required touch detection density in order to ensure the required touch detection density. For example, the self-capacitance electrode may be designed as a square electrode of about 5 mm*5 mm. Since the density of the display screen is usually at micrometer scale, one self-capacitance electrode would generally correspond to a plurality of subpixels in the display screen.

The touch detection chip is used to determine the touch position by detecting variations in the capacitance values of the respective self-capacitance electrodes during the touch time period. The touch detection chip is manufactured using, for example, an integrated circuit (IC) technology. Furthermore, during specific implementation, arrangement of the touch connecting lines can be adjusted according to specific schemes.

On the basis of the same concept, embodiments of the present disclosure further provide a display device comprising the above embedded touch screen as provided. The display device may be a passive matrix organic light-emitting diode (PMOLED) display, wherein the substrate needs an external driving circuit, or may be an active matrix organic light-emitting diode (AMOLED) display, wherein the driving circuit and the display array are integrated on the same substrate.

The display device may be any product or component having display function such as mobile phone, tablet computer, television, display, notebook computer, digital frame, watch, navigator, and so on. The proposed display device implements the touch functionality based on the self capacitance scheme on the basis of the existing organic light-emitting diode display device, without influencing the pixel characteristics of the display device. The signal-to-noise ratio is significantly increased as compared to the mutual capacitance scheme.

Although the illustrative embodiments of the present disclosure have been described in detail with reference to the drawings, such description should be considered to be illustrative or exemplary, rather than limiting. The present disclosure is not limited to the embodiments disclosed. Different embodiments described above and in the claims may also be combined. When implementing the present disclosure, those skilled in the art can understand and implement other variations of the disclosed embodiments based on the study of the drawings, description and claims. These variations also fall within the protection scope of the present disclosure.

In the claims, the word “comprise” does not exclude the existence of other components or steps, and “a” or “an” does not exclude the plural. The fact that several technical measures are stated in different dependent claims does not mean that the combination of these technical measures cannot be advantageously utilized.

1. An embedded touch screen, comprising:
an array substrate having a plurality of subpixels, each subpixel comprising an organic light-emitting diode;
a plurality of gate lines and data lines arranged on the array substrate which intersect each other and are insulated from each other, the gate lines and the data lines intersecting each other to define the plurality of subpixels;
a plurality of self-capacitance electrodes which are arranged in the same layer and independent from each other; and
a plurality of touch connecting lines for connecting respective self-capacitance electrodes to a touch detection chip,
wherein the self-capacitance electrodes are arranged in the same layer as anodes of organic light-emitting diodes.

2. The embedded touch screen according to claim 1, wherein the anodes of organic light-emitting diodes are of discrete structure, each anode corresponding to one subpixel, and each self-capacitance electrode is arranged at a gap between adjacent anodes.

3. The embedded touch screen according to clam 2, wherein a pattern of the self-capacitance electrodes is designed as a grid pattern surrounding the anodes of organic light-emitting diodes.

4. The embedded touch screen according to claim 1 wherein the organic light-emitting diode is a top-emitting structure, wherein a cathode of the organic light-emitting diode has an opening in an area where it overlaps the self-capacitance electrode.

5. The embedded touch screen according to claim 1, wherein opposite sides of two adjacent self-capacitance electrodes have zigzag shapes.

6. The embedded touch screen according to claim 5, wherein opposite sides of two adjacent self-capacitance electrodes have consistent and matching step shapes.

7. The embedded touch screen according to claim 5, wherein opposite sides of two adjacent self-capacitance electrodes have consistent and matching convex-concave shapes.

8. The embedded touch screen according to claim 1, wherein the self-capacitance electrode is designed as a square electrode of 5 mm*5 mm.

9-10. (canceled)

11. The embedded touch screen according to claim 2, wherein the organic light-emitting diode is a top-emitting structure, wherein a cathode of the organic light-emitting diode has an opening in an area where it overlaps the self-capacitance electrode.

12. The embedded touch screen according to claim 2, wherein opposite sides of two adjacent self-capacitance electrodes have zigzag shapes.

13. The embedded touch screen according to claim 12, wherein opposite sides of two adjacent self-capacitance electrodes have consistent and matching step shapes.

14. The embedded touch screen according to claim 12, wherein opposite sides of two adjacent self-capacitance electrodes have consistent and matching convex-concave shapes.

15. The embedded touch screen according to claim 2, wherein the self-capacitance electrode is designed as a square electrode of 5 mm*5 mm.

16. A display device comprising an embedded touch screen, the embedded touch screen comprising:
an array substrate having a plurality of subpixels, each subpixel comprising an organic light-emitting diode;
a plurality of gate lines and data lines arranged on the array substrate which intersect each other and are insulated from each other, the gate lines and the data lines intersecting each other to define the plurality of subpixels;
a plurality of self-capacitance electrodes which are arranged in the same layer and independent from each other; and
a plurality of touch connecting lines for connecting respective self-capacitance electrodes to a touch detection chip,
wherein the self-capacitance electrodes are arranged in the same layer as anodes of organic light-emitting diodes.

17. The display device according to claim 16, wherein the anodes of organic light-emitting diodes are of discrete structure, each anode corresponding to one subpixel, and each self-capacitance electrode is arranged at a gap between adjacent anodes.

18. The display device according to claim 17, wherein a pattern of the self-capacitance electrodes is designed as a grid pattern surrounding the anodes of organic light-emitting diodes.

19. The display device according to claim 16, wherein the organic light-emitting diode is a top-emitting structure, wherein a cathode of the organic light-emitting diode has an opening in an area where it overlaps the self-capacitance electrode.

20. The display device according to claim 16, wherein opposite sides of two adjacent self-capacitance electrodes have zigzag shapes.

21. The display device according to claim 20, wherein opposite sides of two adjacent self-capacitance electrodes have consistent and matching step shapes.

22. The display device according to claim 16, wherein the display device is a passive matrix organic light-emitting diode display or an active matrix organic light-emitting diode display.
